(19) United States
(12) Patent Application Publication
(10) Pub. No.: US 2024/0012063 A1
(43) Pub. Date: Jan. 11, 2024

(54) STATE OF HEALTH BASED OPERATION FOR VEHICLE POWER SOURCES`

(71) Applicant: GM GLOBAL TECHNOLOGY OPERATIONS LLC, Detroit, MI (US)

(72) Inventors: Jingyuan LIU, Shanghai (CN); Dave G. RICH, Sterling Heights, MI (US); Manjit SWAMI, Westland, MI (US); Charles W. WAMPLER, II, Birmingham, MI (US); Dewen KONG, Shanghai (CN)

(21) Appl. No.: 17/889,440

(22) Filed: Aug. 17, 2022

(30) Foreign Application Priority Data
Jul. 5, 2022 (CN) 202210782766.4

(51) Int. Cl. G01R 31/392; H02J 7/00; G01R 31/3835; B60L 58/12; B60L 58/16; B60L 53/00

(52) U.S. Cl. CPC G01R 31/392; H02J 7/0048; H02J 7/005; H02J 7/00712; H02J 7/0068; G01R 31/3835; B60L 58/12; B60L 58/16; B60L 53/00

(57) ABSTRACT

A state of health (SOH) based control system includes: a memory configured to store an algorithm including instructions for determining a SOH of a power source; and a control module configured to receive a voltage signal indicating a voltage of the power source and execute the instructions. The instructions include: determining a state of charge (SOC) of the power source; generating a differential signal based on a change in the voltage and a change in the state of charge; determining an inflection point and an end of charge point of the differential signal; determining the SOH of the power source based on the inflection point and the end of charge point; and performing at least one of a control operation or a countermeasure based on the SOH.

### CROSS-REFERENCE TO RELATED APPLICATIONS

This application claims the benefit of Chinese Patent Application No. 202210782766.4, filed on Jul. 5, 2022. The entire disclosure of the application referenced above is incorporated herein by reference.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to power source monitoring systems and more particularly to state of health monitoring systems.

Hybrid and electric vehicles can include one or more electric motors for propulsion. The electric motors can be powered by one or more electrical power sources, such as one or more battery packs. The battery packs may include cells that are connected in series and/or parallel to provide power to various loads. The cells may include capacitive assisted battery (CAB) cells. Each CAB cell may include a capacitor, which responds to fast changes in charging current.

### SUMMARY

A state of health (SOH) based control system is disclosed and includes: a memory configured to store an algorithm including instructions for determining a SOH of a power source; and a control module configured to receive a voltage signal indicating a voltage of the power source and execute the instructions. The instructions include: determining a state of charge (SOC) of the power source; generating a differential signal based on a change in the voltage and a change in the state of charge; determining an inflection point and an end of charge point of the differential signal; determining the SOH of the power source based on the inflection point and the end of charge point; and performing at least one of a control operation or a countermeasure based on the SOH.

In other features, the control module is configured to differentiate voltage versus charge of the power source to provide the differential signal.

In other features, the inflection point is at least one of a last inflection point in a charge cycle of the power source or a first inflection point in a discharge cycle of the power source.

In other features, the end of charge point refers to a SOC between a SOC of the inflection point and a full or near full SOC of the power source.

In other features, the end of charge point refers to a full or near full SOC of the power source.

In other features, the control module is configured to discharge the power source to a point after detection of the inflection point and then charge the power source to the end of charge point to estimate the SOH.

In other features, the control module is configured to charge the power source to the end of charge point and then discharge the power source past the inflection point to estimate the SOH.

In other features, the control module is configured to charge the power source from an intermediate SOC below a SOC of the inflection point to the end of charge point to estimate the SOH.

In other features, the control module is configured to determine a logarithm of the differential signal, and based on the algorithm of the differential signal, determine the inflection point and the end of charge point.

In other features, the control module is configured to determine the end of charge point based on the inflection point.

In other features, the control module is configured to filter at least one of the voltage signal and the differential signal to provide a filtered differential signal, and based on the filtered differential signal, determine the inflection point and the end of charge point.

In other features, the control operation includes at least one of charging or loading the power source based on the SOH of the power source.

In other features, the SOH based control system further includes sensors configured to generate the voltage signal and a charge signal, the charge signal indicating the SOC of the power source. The control module is configured to determine the SOC based on the charge signal.

In other features, a vehicle system is provided and includes: the SOH based control system; and loads of a vehicle. The control module is configured, based on the SOH, to control loading of the power source including selective connection of the power source to one or more of the loads.

In other features, a SOH based method is disclosed and includes: receiving a voltage signal at a control module indicating a voltage of a power source; determining a SOC of the power source; generating a differential signal based on a change in the voltage and a change in the state of charge; determining an inflection point and an end of charge point of differential signal; determining the SOH of the power source based on the inflection point and the end of charge point; and performing at least one of a control operation or a countermeasure based on the SOH.

In other features, the SOH based method further includes differentiating voltage versus charge of the power source to provide the differential signal.

In other features, the inflection point is at least one of a last inflection point in a charge cycle of the power source or a first inflection point in a discharge cycle of the power source.

In other features, the end of charge point refers to a SOC between a SOC of the inflection point and a full or near full SOC of the power source.

In other features, the end of charge point refers to a full or near full SOC of the power source.

In other features, the SOH based method further includes at least one of: discharging the power source to a point after detection of the inflection point and then charging the power source to the end of charge point to estimate the SOH; charging the power source to the end of charge point and then discharging the power source past the inflection point to estimate the SOH; or charging the power source from an intermediate SOC below a SOC of the inflection point to the end of charge point to estimate the SOH.

In other features, the SOH based further includes determining a logarithm of the differential signal, and based on the logarithm of the differential signal, determining the inflection point and the end of charge point.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a propulsion system including a state of health (SOH) estimation module in accordance with the present disclosure;

FIG. 2 is a functional block diagram of an example multiple output dynamically adjustable capacity system (MODACS) in accordance with an embodiment of the present disclosure;

FIGS. 3A-3B are a schematic including an example implementation of a MODACS in accordance with an embodiment of the present disclosure;

FIG. 4 is an electrical schematic of a CAB module including a CAB and a switch;

FIG. 5 is a schematic and functional block diagram of a battery management system monitoring circuit in accordance with the present disclosure;

FIG. 6 is a functional block diagram of a SOH monitoring system in accordance with the present disclosure;

FIG. 7 is an example voltage versus capacity plot illustrating different voltage versus capacity curves for different full states of charge of a cell;

FIG. 8 is an example dual-plot diagram illustrating relationship between voltage versus capacity curves and derivative of voltage with respect to charge versus capacity curves used in a first SOH estimation method in accordance with the present disclosure;

FIG. 9 is an example multi-plot diagram including voltage versus capacity curves, derivative of voltage with respect to charge versus capacity curves, and derivative of voltage with respect to charge versus state of charge (SOC) curves illustrating an unknown profile aspect and a SOH changing tendency used in a second SOH estimation method in accordance with the present disclosure;

FIG. 10 is an example dual-plot diagram illustrating a third SOH estimation method starting from a high SOC and initially discharging in accordance with the present disclosure;

FIG. 11 is another example dual-plot diagram illustrating a fourth SOH estimation method starting from a high SOC and initially charging in accordance with the present disclosure;

FIG. 12 is another example dual-plot diagram illustrating a fifth SOH estimation method starting from an intermediate to low SOC and initially charging in accordance with the present disclosure;

FIG. 13 is an example plot illustrating a sixth SOH estimation method based on an inflection point SOC and an end of charging point in accordance with the present disclosure;

FIG. 14 is an example plot illustrating absence of an inflection point for end of life (EOL) detection according to a seventh SOH estimation method in accordance with the present disclosure;

FIG. 15 is a plot illustrating magnitudes of inflection points of derivative of voltage with respect to charge versus SOC curves in accordance with the present disclosure;

FIG. 16 is a plot illustrating magnitudes of and inflection points of logarithmic versions of the derivative of voltage with respect to charge versus capacity curves in accordance with the present disclosure; and

FIG. 17 illustrates a SOH based method in accordance with the present disclosure.

In the drawings, reference numbers may be reused to identify similar and/or identical elements.

### DETAILED DESCRIPTION

The state of health (SOH) of a power source may be monitored to, for example, determine remaining life of the power source. System control operations may also be based on the SOH of the power source. Identifying the SOH of a battery can be determined to maximize usage of battery capacity. As an example, a battery may be charged from a low state of charge (SOC) to a high and/or full SOC. Over time the capacity of a battery decreases, such that the full SOC is less than the full SOC when new. The SOH of the battery may be determined to reconfirm whether the battery still has the original full SOH or a reduced level of SOH. The process to determine the SOH can take a long time and is unable to be performed frequently. More accurate SOH can lead to optimized system performance and reduced battery costs. A SOH process can limit battery functionality during highest/lowest parts of a charge/discharge cycle.

The examples set forth herein include estimating the SOH of batteries, such as capacitor assisted batteries (CABs) or other types of batteries based on a derivative of voltage with respect to charge or dV/dQ, where V is voltage and Q is charge. This determination may be utilized in a modular dynamically allocated capacity storage system (MODACS), where a short range SOC may be determined instead of a long range SOC to determine the SOH. A short range SOC is determined more quickly than a long range SOC, hence use of the phrase “short range”. A short range SOC may be determined over a period when a battery is charged from an intermediate SOC to a high and/or full SOC. For example, the intermediate SOC may refer to a SOC below a first one or more inflection points in a dV/dQ profile relating dV/dQ to capacity. A first inflection point may refer to an inflection point closest to a high SOC and/or high dV/dQ value, as further described below.

The examples include use of dV/dQ curve-based algorithms, which determine SOHs of power sources based on inflection points in dV/dQ curves. The inflection points of the dV/dQ curves shift as SOH vary. This shift is accounted for and used as an index to track SOH status values of a CAB power source. A CAB power source may refer to one or more CAB cells and/or one or more CAB batteries. In some examples, capacity decay between i) a full SOC and ii) a capacity level at inflection point, is used to estimate SOH. In other examples, a logarithmic of dV/dQ profiles are used to estimate SOH. The SOH is based on a difference between a capacity at a full SOC and a capacity at an inflection point. These are efficient and reliable methods for estimating SOH. The examples account for loss-of-Li.

The disclosed examples include characterization analysis of power sources including determining various power source characterization parameters, such as SOC, SOH, temperature, etc. The characterization parameters may be determined based on impedance responses and/or other parameters. SOC refers to a level of charge of a power source relative to a capacity of the power source. The SOC of a cell may refer to the voltage, current and/or amount of available power stored in the cell. SOH refers to a ratio of a current maximum charge of a power source relative to a rated capacity of the power source. SOH is related to aging of the power source. SOH of a cell may refer to: the age (or operating hours); whether there is a short circuit; temperatures, voltages, and/or current levels supplied to or sourced from the cell during certain operating conditions; and/or other parameters describing the health of the cell. The SOH may refer to i) a ratio of a remaining and/or capacity and an initial capacity when the power source is new, and/or ii) a ratio of a remaining full SOC and an initial full SOC when new. The acronym “SOX” refers to a state of charge (SOC), a state of health (SOH), and/or a state of function (SOF). The SOF of a cell may refer to a current temperature, voltage, and/or current level supplied to or sourced from the cell, and/or other parameters describing a current functional state of the cell.

The characterization parameters may be used for power source allocation and control and for thermal mitigation purposes. The characterization analysis may be embedded into a power source charging process and/or service to monitor the characterization parameters for control, diagnostic and prognostic purposes. The diagnostic and prognostic operations may be predictive.

The term “power source” as used herein may refer to a battery pack, a battery module of a battery pack, and/or one or more cells of a battery module of a battery pack. A battery pack may include multiple battery modules, which in turn may each include hundreds of cells. Thus, a power source may include multiple power sources. A power source may further include a cooling circuit, sensors, switches, terminals, a control module, etc.

The implementations disclosed herein may be applied to fully electric vehicles, battery electric vehicles (BEVs), hybrid electric vehicles including pug-in hybrid electric vehicles (PHEVs), partially or fully autonomous vehicles, and other types of vehicles.

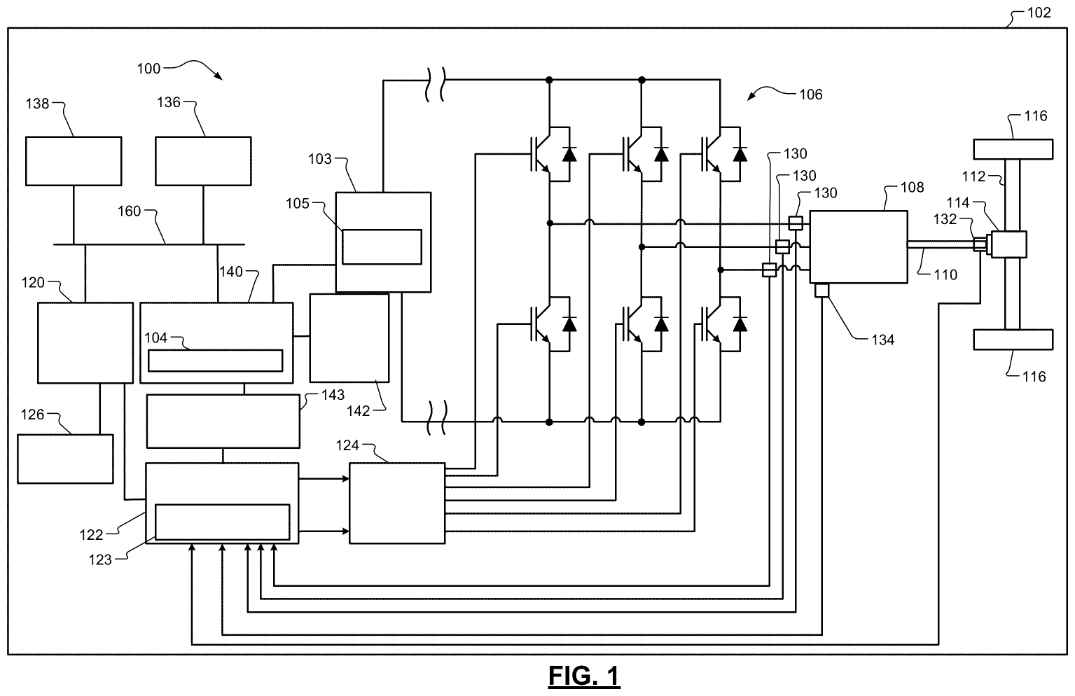

FIG. 1 shows a propulsion system 100 of a vehicle 102 that includes a MODACS 103 including power sources 105. The propulsion system 100 is provided as an example, the methods, algorithms and embodiments disclosed herein are applicable to other propulsion and non-propulsion systems. The power sources 105 may include any number of cells, battery modules, and/or battery packs. Each battery pack may include any number of battery modules and each battery module may include and number of cells.

The MODACS 103 may be implemented as a single battery having a corresponding housing with a negative (or ground reference) terminal and multiple source terminals. Each of the source terminals of a MODACS may have a preset direct current (DC) voltage (e.g., 12 volts (V) or 48V) and may supply (or discharge) current or receive current during charging. As an example, the MODACS 103 may include a single 48V source terminal, a first 12V source terminal and a second 12V source terminal.

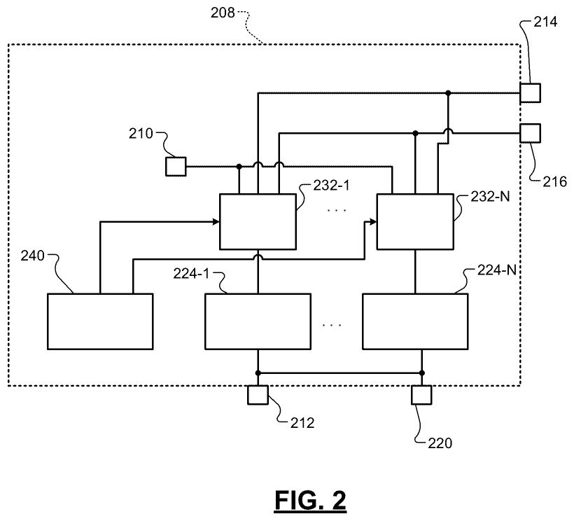

The MODACS 103 includes multiple battery cells (hereinafter referred to as cells) and a MODACS control module (shown in FIG. 2). The MODACS control module may be attached to, implemented in or be connected externally to the housing of the MODACS. The MODACS control module may be implemented partially or fully at the housing or at a remote location. As an example, the MODACS control module may be implemented as a control module within a vehicle and/or as part of a vehicle control module.

The housing may include switches and battery monitoring (or management) modules (BMSs). The switches and BMSs may be connected to and/or implemented separate from the cells. The MODACS control module controls operating states of the switches to connect selected ones of the cells to the source terminals based on information from the BMSs. Any number of the cells may be selected and connected to each of the source terminals. The same or different cells may be connected to each of the source terminals at any moment in time. As further described below, the cells may be connected: in series and/or in parallel; in different connected configurations; and may be organized into blocks, packs, and/or groups. Each block may include one or more cells, which may be connected in series and/or in parallel. Each pack may include one or more blocks, which may be connected in series and/or in parallel. Each group may include one or more packs, which may be connected in series and/or in parallel. The groups may be connected in series and/or in parallel. Each of the BMSs may be assigned to one or more cells, one or more blocks, one or more packs, and/or one or more groups and monitor corresponding parameters, such as voltages, temperatures, current levels, SOXs, instantaneous power and/or current limits, short-term power and/or current limits, and/or continuous power and/or current limits.

The MODACS 103 may supply power to an inverter 106, which in turn drives a motor 108 (e.g., an interior permanent magnet (IPM) motor). Although the motor 108 is shown as an IPM motor, the motor 108 may be a surface permanent magnet motor or other type of electric motor. Although various examples are disclosed herein with respect to a motor, the examples are applicable to other electric machines. The MODACS (or power source) 103 may include multiple cells, battery modules and/or battery packs that are connected in series and/or in parallel to provide predetermined voltage outputs.

The propulsion system 100 is used to move the vehicle 102 and further includes a shaft 110, an axle 112 including a differential 114 and wheels 116. The inverter 106 converts a DC voltage to a three-phase alternating current (AC) to power the motor 108. The motor 108 rotates the shaft 110, which in turn rotates the axle 112 via the differential 114.

The propulsion system 100 further includes a vehicle control module 120, a propulsion control module 122 and a driver 124. The vehicle control module 120 may generate a torque request signal. The torque request signal may be generated based on torque commanded, for example, by an accelerator 126 if included. The propulsion control module 122 may control the driver 124 based on the torque request signal. The driver 124 may, for example, generate pulse width modulation (PWM) signals to control states of transistors of the inverter 106 based on output of the propulsion control module 122.

The propulsion control module 122 may include a bus current control module 123, which may implement an algorithm to generate frequency discharge current pulses for one or more power sources (e.g., cells and/or modules of the battery packs 105). The bus current control module 123 generates frequency discharge current pulses via the inverter 106 that are experienced by the one or more power sources. A battery management module 140 detects current and voltage levels of the one or more power sources to determine impedance responses of the one or more power sources. A different frequency signal (or pulsed signal) may be experienced by different cells, battery modules and/or battery packs based on selective coupling of the cells, battery modules and/or battery packs to the inverter. As an example, each battery module may have a respective chemical makeup, size, shape, etc. and thus be allocated a respective set of one or more frequency signals. Each frequency signal may have a respective duty cycle profile, amplitude profile, and frequency profile. In one embodiment, a same set of frequency signals are generated and experienced by two or more power sources.

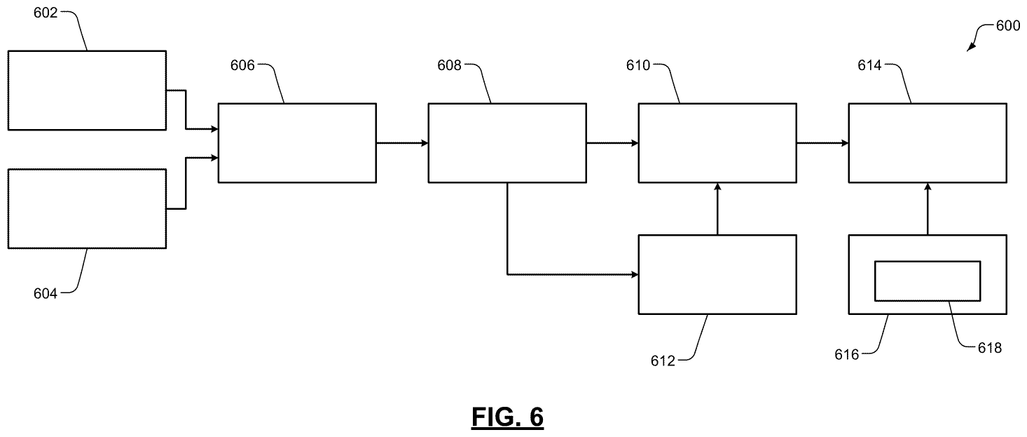

Application of the frequency signals and monitoring of impedance responses of the power sources allows for on-board characterization analysis of the power sources. Impedances may be calculated and stored in memory 143. The battery management module 140 may store the impedance responses and/or impedance values in the memory 143. Impedance response determination is further described below with respect to FIGS. 2-11. The battery management module 140 may include a SOH estimation module 104, which monitors the SOH of one or more power sources of the MODACS 103. The SOH estimation module 104 is further described below with respect to FIGS. 6-18.

The propulsion control module 122 controls the driver 124 based on outputs from sensors. The sensors may include current sensors (e.g., Hall Effect sensors 130), a resolver 132, a temperature sensor 134, and/or other sensors 136 (e.g., an accelerometer). The current sensors may include sensors other than Hall Effect sensors. The sensors may include the power source sensors 142.

The propulsion control module 122 performs a transformation of current phase signals Ia, Ib and Ic for the three phases of the motor to current vector signals Id and Iq. The propulsion control module 122 determines how much current is flowing and how much current is needed (or requested) and modifies input current levels of the motor 108 by adjusting output voltage vector signals supplied to the driver 124. This is based on (i) the current vector signals Id, Iq, (ii) the position signal out of the resolver 132, and (iv) the torque request signal from the vehicle control module 120.

A propulsion system 100 may include one or more electric motors. Each electric motor may be used to drive one or more axles and/or one or more wheels of the vehicle 102. As an example, an electric motor may be used to drive an axle of the vehicle 102 via a differential. The vehicle control module 120, based on a torque request, may signal the electric motor to rotate an input gear of the differential and as a result, the wheels attached to the axle. The vehicle control module 120 may adjust current, voltage and/or power levels of the electric motor to control acceleration, deceleration and/or speed of the vehicle 102.

The propulsion system 100 further includes a telematics module 138, the battery management module 140 and power source sensors and/or status monitoring devices (referred to as power source sensors 142). The battery management module 140 is part of a SOH based control system including the MODACS 103 and power source sensors 142. The battery management module 140 may configure the MODACS 103 as further described below based on output of the above-stated sensors, speed requests, current traveling speed, torque requests, charge states of battery packs of the MODACS 103, etc. The power source sensors 142 may include voltage sensors, current sensors, coulombic counters, and/or other circuit elements used to monitor open circuit voltages (VOCs), SOCs and/or capacities of the power sources 105 and/or cells and/or modules of the power sources 105. The power source sensors 142 may be separate from the power sources 105 or included in the power sources 105 and monitor voltages, current levels, SOCs, VOCs, capacities, etc. of cells and/or modules of the battery packs and/or each of the power sources 105 as a whole unit. The battery management module 140 may isolate one or more cells and/or power sources 105 when: operating inappropriately; not charging to a predetermined voltage level; outputting a voltage and/or an amount of current at level(s) below predetermined minimum level(s); and/or exhibiting another abnormality. The modules 120, 138, 140, and sensors 136 may be connected and/or communicate with each other via a network 160 or other form of communication.

FIG. 2 shows an example of the MODACS 103 of FIG. 1, which is designated 208. The MODACS 208 may be implemented as a single battery having multiple source terminals. Three example source terminals 210, 214, 216 are shown, although any number of source terminals may be included. The source terminals, which may be referred to as positive output terminals, provide respective direct current (DC) operating voltages. The MODACS 208 may include only one negative terminal or may include a negative terminal for each source terminal. For example only, the MODACS 208 may have a first positive (e.g., 48Volt (V)) terminal 210, a first negative terminal 212, a second positive (e.g., a first 12V) terminal 214, a third positive (e.g., a second 12V) terminal 216, and a second negative terminal 220. While the example of the MODACS 208 having a 48V operating voltage and two 12V operating voltages is provided, the MODACS 208 may have one or more other operating voltages, such as only two 12V operating voltages, only two 48V operating voltages, two 48V operating voltages and a 12V operating voltage, or a combination of two or more other suitable operating voltages.

The MODACS 208 includes cells and/or blocks of cells, such as a first block 224-1 to an N-th block 224-N (“blocks 224”), where N is an integer greater than or equal to 2. Each of the blocks 224 may include one or more cells and may be separately replaceable within the MODACS 208. For example only, each of the blocks 224 may be an individually housed 12V DC battery. The ability to individually replace the blocks 224 may enable the MODACS 208 to include a shorter warranty period and have a lower warranty cost. The blocks 224 are also individually isolatable, for example, in the event of a fault in a block. In various implementations, the MODACS 208 may have the form factor of a standard automotive grade 12V battery.

Each of the blocks 224 has its own separate capacity (e.g., in amp hours, Ah). The MODACS 208 includes switches, such as first switches 232-1 to 232-N (collectively “switches 232”). The switches 232 enable the blocks 224 to be connected in series, parallel, or combinations of series and parallel to provide desired output voltages and capacities at the output terminals.

A MODACS control module 240 controls the switches 232 to provide desired output voltages and capacities at the source terminals. The MODACS control module 240 controls the switches 232 to vary the capacity provided at the source terminals based on a present operating mode of the vehicle, as discussed further below.

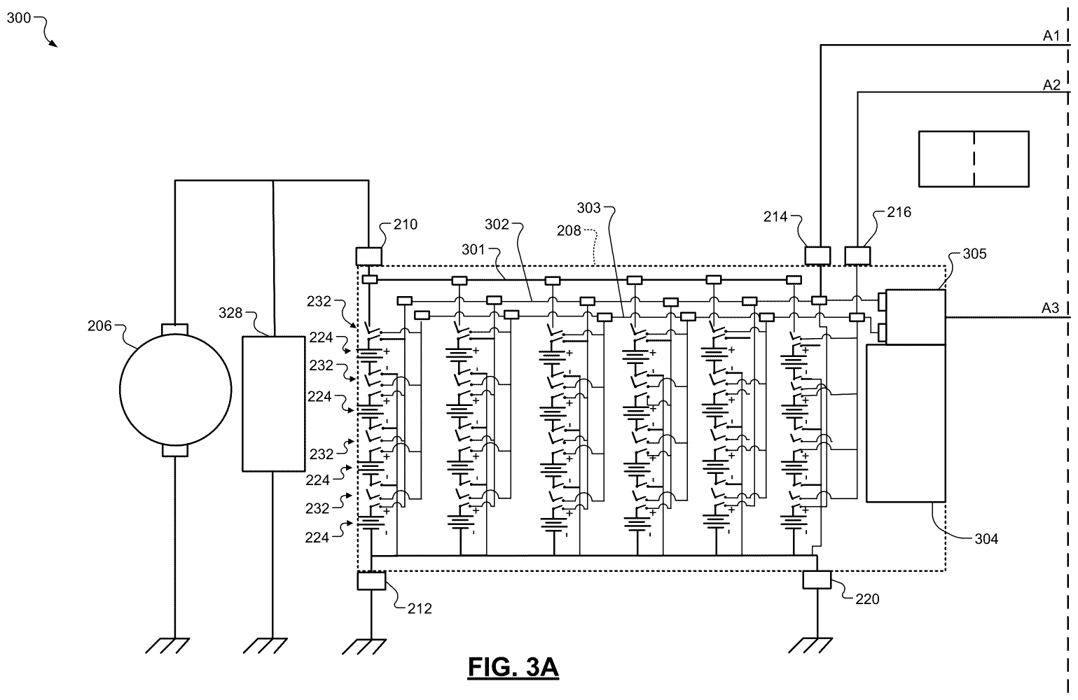

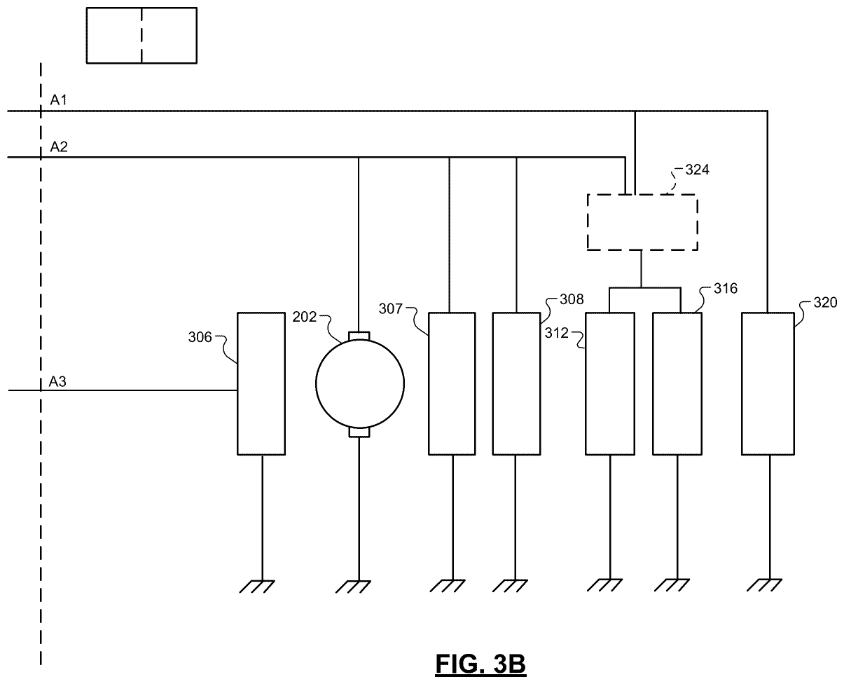

FIGS. 3A-3B show a vehicle electrical system 300 including an example implementation of the MODACS 208. The MODACS 208 includes the source terminals 210, 214, 216, respective power rails 301, 302, 303, a MODACS control module 304, and a power control circuit 305, which may be connected to the MODACS control module 304 and vehicle control module (VCM) and/or body control module (BCM) 306. The VCM and/or BCM 306 may operate similar as, include and/or be implemented as the battery management module (BMM) 140 of FIG. 1. Power rail 303 may be a redundant power rail and/or used for different loads than the power rail 302. The MODACS control module 304, the power control circuit 305 and the VCM and/or BCM 306 may communicate with each other via a controller area network (CAN), a local interconnect network (LIN), a serial network, wirelessly and/or another suitable network and/or interface. The MODACS control module 304 may communicate with the VCM and/or BCM 306 directly or indirectly via the power control circuit 305 as shown.

In the example of FIG. 3A, sets of 4 of the blocks 224 (e.g., 12V blocks) are connectable in series (via ones of the switches 232) to the first positive terminal 210 and the first negative terminal 212 to provide a first output voltage (e.g., 48V). Individual ones of the blocks 224 may be connected (via ones of the switches 232) to the second positive terminal 214 or the third positive terminal 216 and the second negative terminal 220 to provide a second output voltage (e.g., 12V) at the second and third positive terminals 214 and 216. How many of the blocks 224 are connected to the first positive terminal 210, the second positive terminal 214, and the third positive terminal 216 dictates the portions of the overall capacity of the MODACS 208 available at each of the positive terminals.

As shown in FIG. 3B, a first set of vehicle electrical components operates using one of the two or more operating voltages of the MODACS 208. For example, the first set of vehicle electrical components may be connected to the second and third positive terminals 214 and 216. Some of the first set of vehicle electrical components may be connected to the second positive terminal 214, and some of the first set of vehicle electrical components may be connected to the third positive terminal 216. The first set of vehicle electrical components may include, for example but not limited to, the VCM and/or BCM 306 and other control modules of the vehicle, the starter motor 202, and/or other electrical loads, such as first 12V loads 307, second 12V loads 308, other control modules 312, third 12V loads 316, and fourth 12V loads 320. In various implementations, a switching device 324 may be connected to both of the first and second positive terminals 214. The switching device 324 may connect the other control modules 312 and the third 12V loads 316 to the second positive terminal 214 or the third positive terminal 216.

As shown in FIG. 3A, a second set of vehicle electrical components operates using another one of the two or more operating voltages of the MODACS 208. For example, the second set of vehicle electrical components may be connected to the first positive terminal 210. The second set of vehicle electrical components may include, for example but not limited to, the generator 206 and various electrical loads, such as 48V loads 328. The generator 206 may be controlled to recharge the MODACS 208.

Each of the switches 232 may be an insulated gate bipolar transistor (IGBT), a field effect transistor (FET), such as a metal oxide semiconductor FET (MOSFET), or another suitable type of switch.

The power sources including the MODACS and CAB modules referred to herein can be used in other applications including non-vehicle applications.

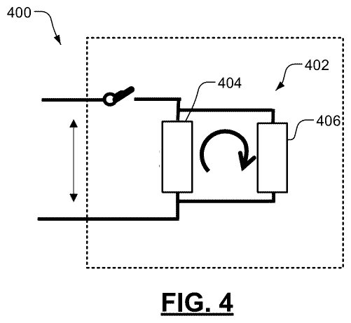

FIG. 4 shows a switched CAB module 400 that includes a switch SW connected in series with a CAB 402. The CAB 402 includes a positive terminal, a negative terminal and a capacitor 404 and a battery 406 connected between the positive terminal and the negative terminal of the CAB 402.

During recharging or regeneration, batteries without capacitors are not able to respond to fast changes in charging current, which reduces overall efficiency. Adding the capacitor 404 to the CAB 402 allows the CAB 402 to respond to fast changes in charging current. During charging, the capacitor 404 initially absorbs power and then the power is redistributed to the battery 406.

The switched CAB module 400 provides improved performance relative to a standard battery without capacitors during periods when fast changes in current occur within a short period of time, especially at low temperatures. However, some of the switched CAB modules 400 are unable to respond to power generated during regeneration events above a predetermined power level within a predetermined period. For example, a rise time or response time of the switch SW may limit the response of the switched CAB module 400 in these conditions. Although a discrete capacitor, a discrete switch and a discrete battery are shown, the switched CAB module 400 may be implemented as or replaced by an integrated supercapacitor that includes a supercapacitor and a battery disposed in a same electrolyte. The integrated supercapacitor arrangement does not include any switches.

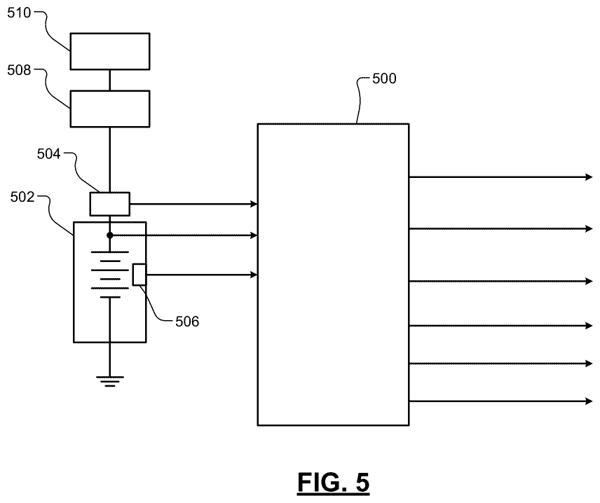

FIG. 5 shows a BMS module 500 for a block or pack 502. In the example shown, the BMS module 500 monitors voltages, temperatures and current levels of the corresponding one or more cells of the block or pack 502 and determines certain parameters. The parameters may include instantaneous charge and discharge power and current limits, short term charge and discharge power and current limits, and continuous charge and discharge power and current limits. The parameters may also include minimum and maximum voltages, minimum and maximum operating temperatures, and SOX limits and/or values. The parameters output by the BMS module 500 may be determined based on the voltages, temperatures and/or current levels monitored. The charge and discharge power and current capability of a 12V block or pack is affected by the minimum and maximum voltages, minimum and maximum operating temperatures, and SOX limits and/or values of the corresponding cells. The BMS module 500 may monitor individual cell voltages, temperatures and current levels and determine based on this information the stated parameters.

As an example, the BMS module 500 may include and/or be connected to sensors, such as a current sensor 504 and a temperature sensor 506, which may be used to detect current levels through the cells of block or pack 502 and temperatures of the block or pack 502. As an example, a voltage across the block or pack may be detected as shown. In an embodiment, one or more voltage sensors may be included to detect voltages of the block or pack 502. The current sensor 504 may be connected, for example, between the block or pack 502 and a source terminal 508, which may be connected to a load 510.

FIG. 6 shows a SOH monitoring system 600 includes a voltage sensor 602, a coulombic counter 604, a differentiator module 606, a filter 608, a distance determining module 610, a logarithmic module 612, a SOH estimation module 614, and a memory 616 that stores a SOH table 618. The voltage sensor 602 may detect voltage output V of a power source, such as any power source referred to herein. The coulombic counter 604 is configured to determine a charge level Q of the power source and generate a charge signal indicating the charge level Q (or SOC). The differentiator module 606 determines dV/dQ of the power source. This may include determining changes in voltage V divided by changes in charge Q and/or determining a derivative of voltage versus charge.

The filter 608 filters the output of the differentiator module 606. The filter 608 may include a Kalman filter, an extended Kalman filter, an adaptive extended Kalman filter, an arithmetic averaging filter, and/or other suitable filter. The filter 608 filters the result of the dV/dQ operation. The output of the filter 608 may be provided to the logarithmic module 612 and to the distance determining module 610. The logarithmic module 612 determines logb(dV/dQ), where base b may be a positive real number not equal to 1. In an embodiment, the base b is 10. The distance determining module 610 determines distances between i) inflection points and ii) high and/or full SOC points (or end of charge points), as further described below. The SOH estimation module estimates the SOH of the power source based on the distances determined by the distance determining module 610. The SOH may be determined using the SOH table 618 (also referred to as a look-up table (LuT)) that relates distances to SOH values for the power source.

Although the filter 608 is shown as filtering the output of the differentiator module 606, the filter 608 may filter the output of the voltage sensor 602. In one embodiment, the outputs of both the voltage sensor 602 and the differentiator module 606 are filtered by respective filters. Thus, a voltage signal out of the voltage sensor 602 and/or a differential signal out of the differentiator module 606 may be filtered.

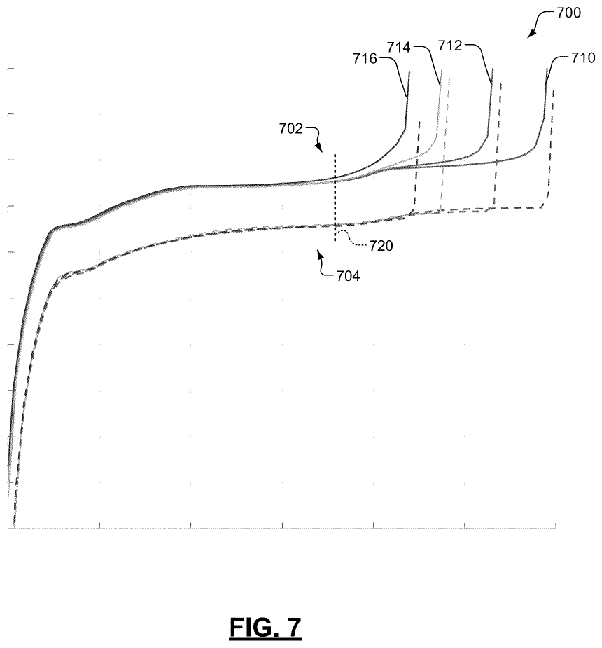

FIG. 7 shows a voltage versus capacity plot 700 of a cell for different full SOCs. The plot includes two sets of curves (or profiles) 702, 704. The first set of curves (or profiles) 702 are charging curves. The second set of curves (or profiles) 704 are discharging curves. The charging curves 702 have respective full SOC portions 710, 712, 714, 716. The full SOC portions are for different portions of the cell's life and are associated with a respective percentage of the full SOC when the cell was new. SOC portion 710 is associated with when the cell is new. SOC portions 712, 714, 716 are associated respectively with 90%, 80%, and 75% of the new cell full SOC. A charging portion of the voltage-capacity profiles respectively of the stated curves may be used to identify respective SOHs of the cell. This determination may be based on inflection points in the curves 702, 704. The plot includes a vertical line 720 that indicates approximately where an inflection point for each of the curves is located.

An inflection point refers to a more steeply sloped portion of a curve interposed between portions of the curve that are generally flat horizontal or more nearly horizontal. An inflection point can occur due to a phase change in material of a cell and/or power source. For example, in a battery, graphite layers receiving ions during charging may transition between lithium carbon LiC24 to LiC12 and/or from LiC12 to LiC6. Using the voltage versus capacity curves 702, 704, it can be difficult to detect inflection points due to the relatively smooth gradual increase in slope.

The following described methods may be implemented by the SOH monitoring system 600 of FIG. 6, the SOH estimation module 104 of FIG. 1, and/or other control module referred to herein. Multiple SOH determination methods are described below and include starting at high and/or full SOCs and finishing at high and/or full SOCs. As an example, the high and/or full SOCs may refer to near full SOCs. For example, a near full SOC may be 95% of a full SOC.

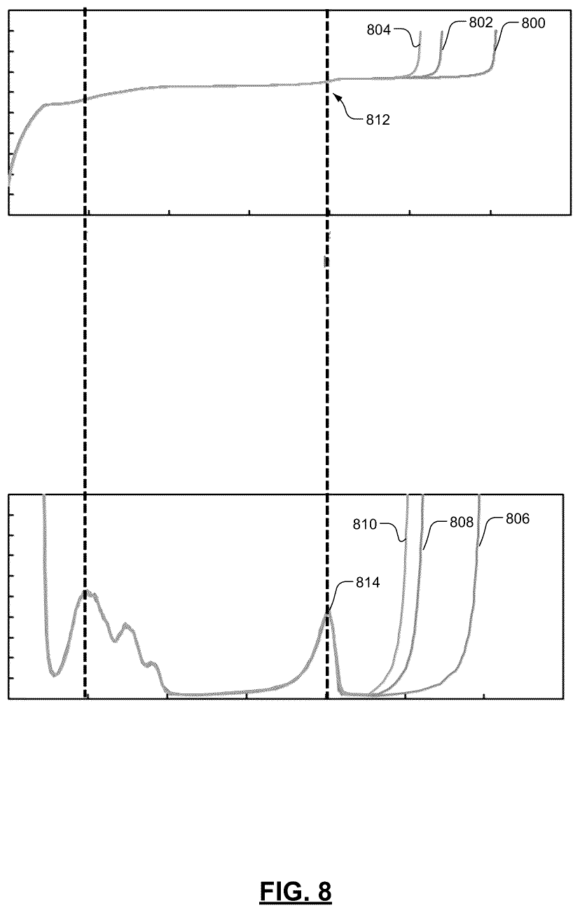

FIG. 8 shows relationship between voltage versus capacity curves 800, 802, 804 and derivative of voltage with respect to charge versus capacity curves 806, 808, 810 used in a first SOH method. The curves have inflection points, designated by arrow 812 and points 814. The inflection points 814 refer to peaks in dV/dQ curves 806, 808, 810 where the dV/dQ curves 806, 808, 810 transition from being positively sloped to being negatively sloped. As can be seen, the dV/dQ curves 806, 808, 810 are similar or the same to the left of the inflection points 814 and begin to change to the right of the inflection points 814. The inflection points 814 may be the last inflection points when charging or the first inflection points when discharging. Since the dV/dQ curves 806, 808, 810 are the same or similar to the left of the inflection points 814 and different to the right of the inflection points 814, the right portions of the dV/dQ curves 806, 808, 810 may be used to determine SOH values respectively for the corresponding power source when exhibiting the charging profiles shown. Thus, the whole charge cycle does not need to be reviewed to determine the SOH values. As can be seen, the inflection points 814 of the dV/dQ curves 806, 808, 810 are more easily detected than the inflection points 812 of the curves 800, 802, 804. In the example shown, the curves 800, 806 may be associated with 100% SOH, curves 802, 808 may be associated with 87% SOH, and the curves 804, 810 may be associated with 83% SOH.

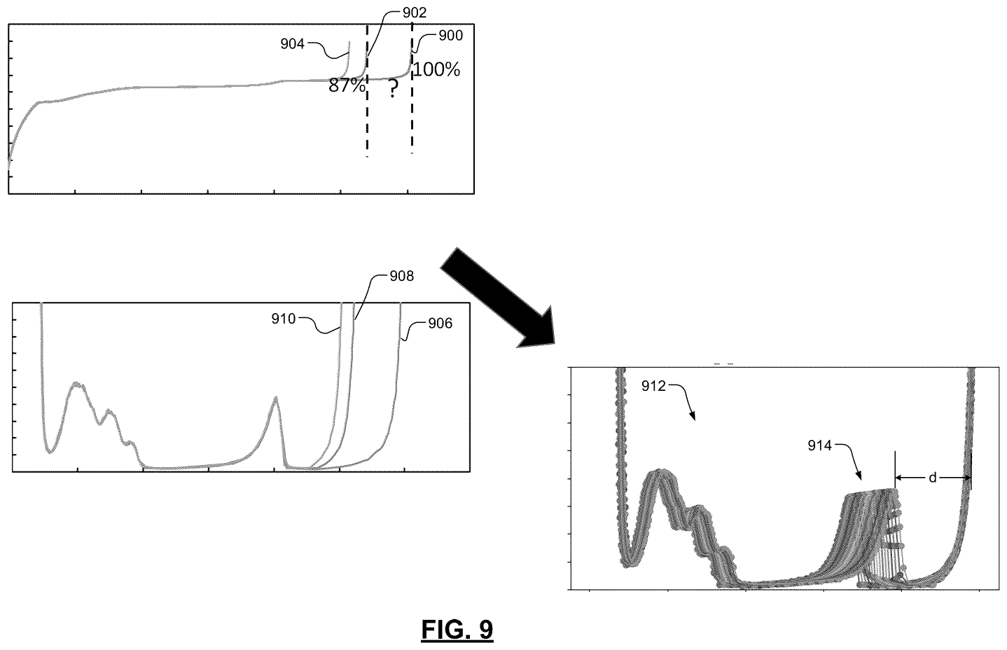

FIG. 9 shows plots of i) voltage versus capacity curves 900, 902, 904, ii) derivative of voltage with respect to charge versus capacity curves 906, 908, 910, and iii) derivative of voltage with respect to charge versus SOC curves 912 illustrating an unknown profile aspect and a SOH changing tendency used in a second SOH method. There are unknown values (designated with a “?” mark in FIG. 9) between test data, for example, in the case shown by curves 900, 902. The curves 900, 902, 904 may be for 100% SOH, 87% SOH, and 83% SOH respectively. Similarly, curves 906, 908, 910 may be for 100% SOH, 87% SOH, and 83% SOH respectively. There is a range of possible curves between curves 900 and 902. The values of these curves may be unknown. Curves 900, 902 (or limited number of test profiles) may not be used for estimating a whole range of SOH values. However, a LuT (e.g., the SOH LuT 618 of FIG. 6) may be generated for a known set of curves, such as curves 912. The LuT may relate distances between inflection points and full SOCs to SOH values, which may be stored in the memory 616 of FIG. 6. The curves 912 may be in 1% SOH increments. For example, the curves 912 may be for 100%, 99%, 98%, 97%, . . . SOH values. An example distance d is shown for the 100% profile curve. Other distances exist for the other ones of the curves 912. The distances are directly related to the SOH values (or SOH percentages). The LuT may relate other values to SOH values. For example, the LuT table may be a dV/dQ table relating dV/dQ values of inflection points 914 of the curves 912 to the SOH values (or SOH percentages).

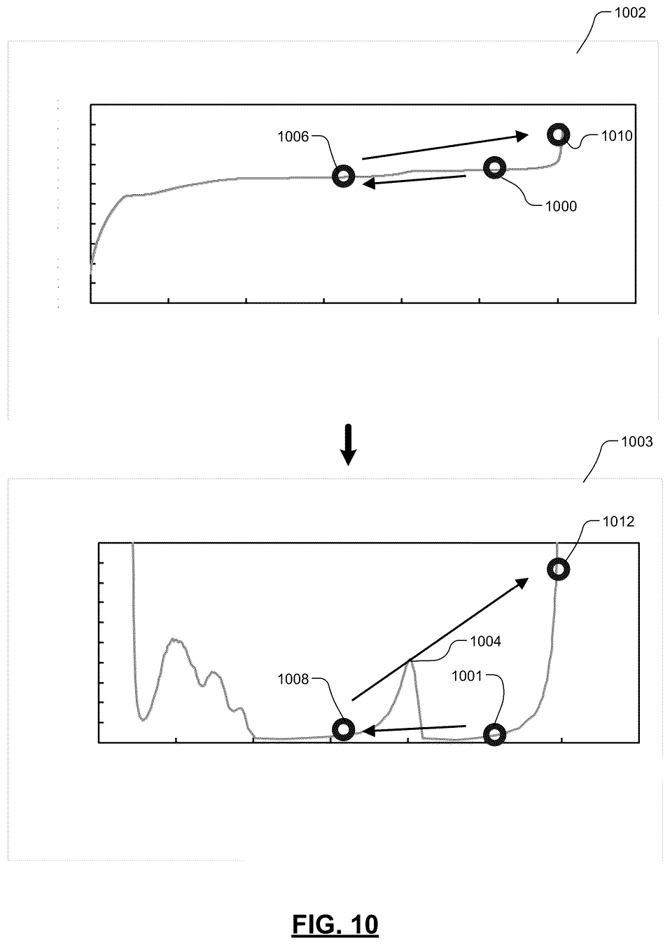

FIG. 10 illustrates a third SOH determination method starting from a high SOC designated by points 1000, 1001 and initially discharging. Two plots 1002, 1003 are shown. The first plot 1002 is a voltage versus capacity plot for a charging profile. The second plot 1003 is a corresponding dV/dQ versus capacity plot for the charging profile. This method includes starting at a high SOC, designated by points 1000, 1001. The point 1001 corresponds to the point 1000 and is higher than a last corresponding dV/dQ inflection point 1004. The corresponding power source is then discharged to point 1006, which has a corresponding point 1008 below the inflection point 1004. The power source is then charged to a full SOC, designated by points 1010, 1012. During these transition periods, the capacity of the power source is recorded in order to determine the SOH of the power source. During these transitions, the SOC of the power source is high and the SOC does not drop down to a low SOC. As an example, the capacity associated with points 1006, 1008 may be greater than 3 amp hours (Ah).

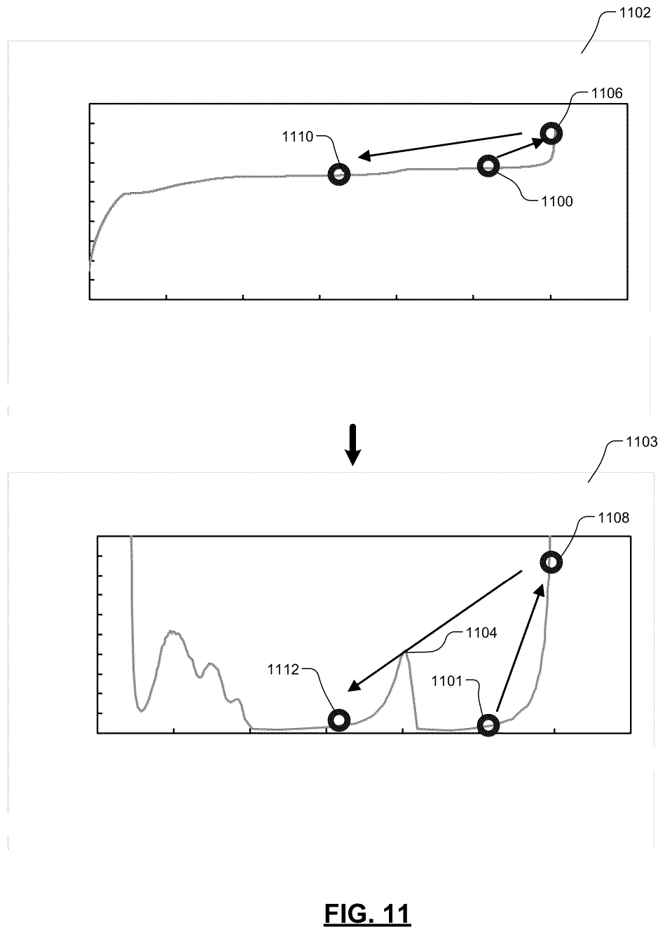

FIG. 11 illustrates a fourth SOH determination method starting from a high SOC 1100 and initially charging. Two plots 1102, 1103 are shown. The first plot 1102 is a voltage versus capacity plot for a charging profile. The second plot 1103 is a corresponding dV/dQ versus capacity plot for the charging profile. This method includes starting at a high SOC, designated by points 1100, 1101. The point 1101 corresponds to the point 1100 and is higher than a last corresponding dV/dQ inflection point 1104. The corresponding power source is then charged to a full SOC designated by point 1106, which has a corresponding point 1108 above the inflection point 1104. The power source is then discharged to a SOC below the inflection point 1104, designated by points 1110, 1112. During these transition periods, the capacity of the power source is recorded in order to determine the SOH of the power source. During these transitions, the SOC of the power source is high, the SOC does not drop down to a low SOC. As an example, the capacity associated with points 1110, 1112 may be greater than 3 amp hours (Ah).

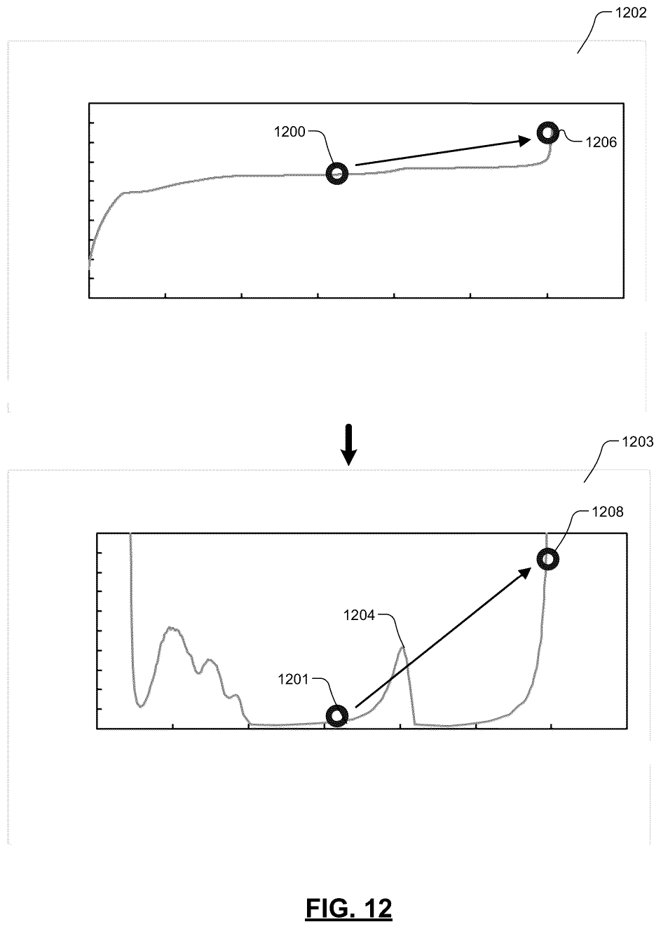

FIG. 12 illustrates a fifth SOH determination method starting from an intermediate to low SOC, designated by point 1200, and initially charging. Two plots 1202, 1203 are shown. The first plot 1202 is a voltage versus capacity plot for a charging profile. The second plot 1203 is a corresponding dV/dQ versus capacity plot for the charging profile. This method includes starting at a high SOC, designated by points 1200, 1201. The point 1201 corresponds to the point 1200 and is below a last corresponding dV/dQ inflection point 1204. The corresponding power source is then charged to a full SOC designated by point 1206, which has a corresponding point 1208 above the inflection point 1204. During this transition period, the capacity of the power source is recorded in order to determine the SOH of the power source. During the stated transition, the SOC of the power source is high and the SOC does not drop down to a low SOC. As an example, the capacity associated with points 1200, 1201 may be greater than 3 amp hours (Ah).

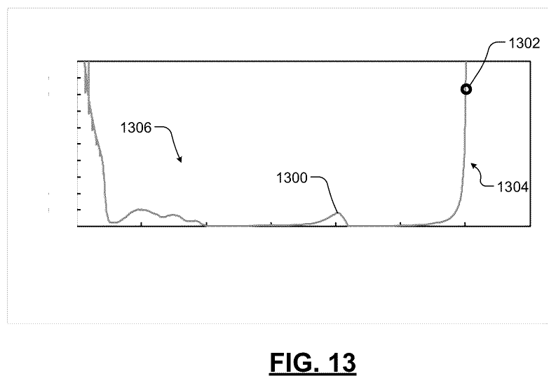

FIG. 13 illustrates a sixth SOH determination method based on inflection point SOC and an end of charging point. FIG. 13 shows a plot of dV/dQ versus capacity including an inflection point 1300 and a full SOC point (or end of charging point) 1302. The dV/dQ value trends towards an infinite value theoretically when the corresponding power source is becoming fully charged, such that an end portion 1304 of the dV/dQ curve 1306 is nearly vertical. An end of charging point is used to track capacity between the inflection point 1300 and the end of charge. In one embodiment, the end of charge (or full SOC) is determined as a product of the peak dV/dQ value at the inflection point 1300 and a predetermined value (e.g., 10). The resulting product may be 99% of a full SOC.

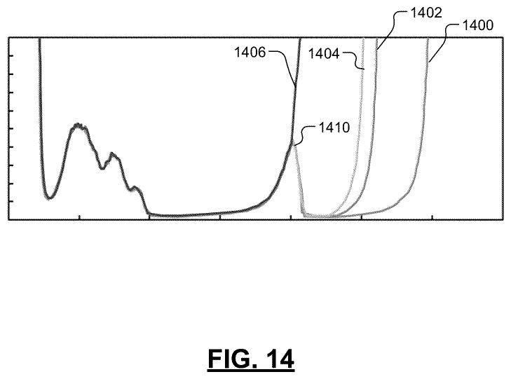

FIG. 14 illustrates absence of an inflection point for end of life (EOL)

detection according to a seventh SOH determination method. FIG. 14 is a plot of dV/dQ curves 1400, 1402, 1404, 1406 for 100% SOH, 87% SOH, 83% SOH and 70% SOH, respectively of a power source. At the end of life of the power source, the last inflection point for charging disappears. This is illustrated by the charging profile for the 70% SOH curve 1406, which does not have the high end inflection point, whereas the curves 1400, 1402, 1404 have inflection points 1410. The inflection points 1410 may be the same point.

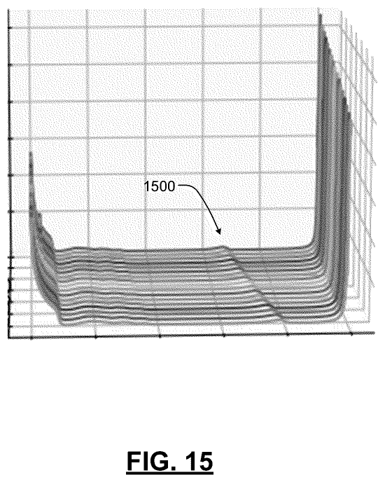

FIG. 15 is a plot illustrating magnitudes in inflection points 1500 of derivative of voltage with respect to charge versus SOC curves. As can be seen, when plotting and reviewing the full charging cycle as a whole, the magnitudes of the inflection points of the curves, designated by arrow 1500, can be small and difficult to detect.

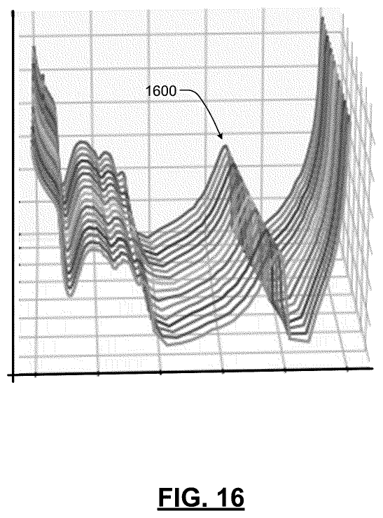

FIG. 16 is a plot illustrating magnitudes in inflection points of logarithmic versions of the derivative of voltage with respect to charge versus capacity curves of FIG. 15. As can be seen, by taking the logarithm of dV/dQ when plotting and reviewing the full charging cycle as a whole, the magnitudes of the inflection points (designated by arrow 1600) are more pronounced, more visible, and easier to detect. The logarithm of dV/dQ may be determined prior to performing one of the methods of FIGS. 9-14 and used to detect inflection points and/or for distance and SOH determinations as described herein.

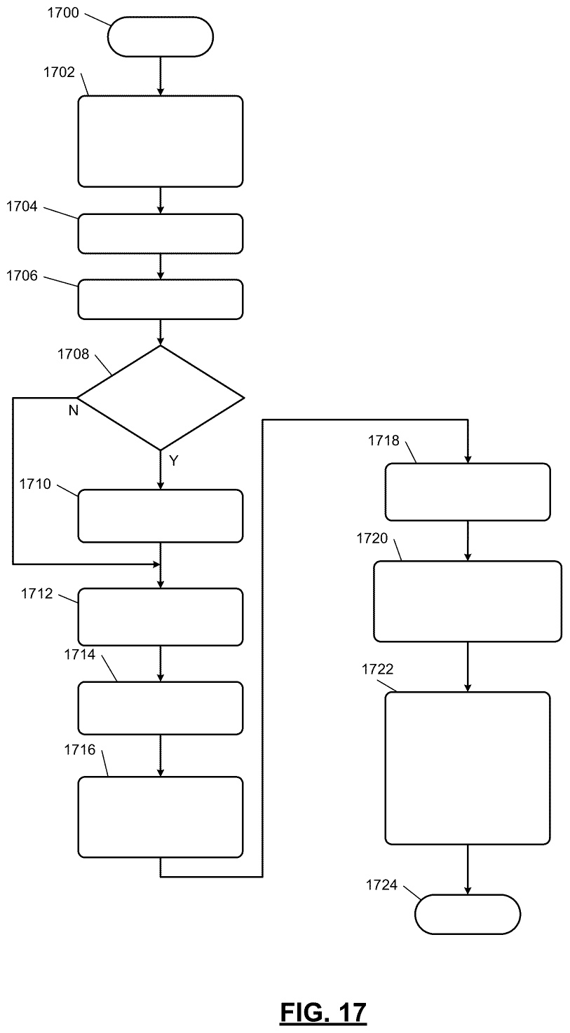

FIG. 17 shows a SOH based method. The SOH based method of claim 17 may be performed concurrently with and/or include any of the above-described methods. The following operations may be iteratively performed. The SOH based method may begin at 1700. At 1702, parameters of a power source, such as any of the power sources referred to herein may be detected and/or determined. The parameters may include, for example, voltage and current of the power source. This may also include determining SOC of the power source based on an output of, for example, the coulombic counter 604 of FIG. 6. The SOC may be determined based on the voltage and/or current of the power source. At 1704, the differentiator module 606 determines dV/dQ based on the voltage and SOC to provide dV/dQ data, which may be in the form of a dV/dQ signal (referred to as a differential signal).

At 1706, the dV/dQ signal may be filtered via the filter 608 to provide a filtered dV/dQ signal, which may be provided to the distance determining module 610 or to the logarithmic module 612.

At 1708, a determination may be made as to whether the logarithm of dV/dQ is to be determined. If yes, operation 1710 is performed, otherwise operation 1712 is performed.

At 1710, the logarithmic module 612 determines logarithm dV/dQ (or logb dV/dQ). This may be the logarithm of the filtered dV/dQ signal. At 1712, the distance determining module 610 detects an inflection point including the SOC at the voltage peak corresponding to the inflection point. This may be based on the filtered dV/dQ signal or the logarithm of the filtered dV/dQ signal. The inflection point may be detected using any of the methods disclosed herein.

At 1714, the distance determining module 610 determines a high and/or full SOC at an end of charge cycle (or beginning of a discharge cycle). In an embodiment, the full SOC is determined. This may be done, for example, using the method of FIG. 13. The high and/or full SOC may thus be determined based on the SOC of the inflection point.

At 1716, the distance determining module determines distance between the SOC of the inflection point and the high and/or full SOC. At 1718, the SOH estimation module 614 estimates the SOH of the power source based on the distance. This may be accomplished using the SOH table 618 and/or other LuT referred to herein.

At 1720, the BMM 140 of FIG. 1 may monitor the SOH and estimate life remaining and/or detect the end of life of the power source. The estimate of life remaining may be time based. An amount of time may be provided based on historical data and the rate of change in the SOH of the power source over time. The amount of time may be based on historical data for other same or similar power sources operating in the same or similar environment and under the same or similar conditions.

At 1722, based on the SOH and/or the estimated amount of life remaining, perform one or more control operations and/or countermeasures. For example, if the SOH is less than a first predetermined SOH, the power source may be fully charged and/or the BMM 140 may permit continued and/or limited use of the power source. This may include loading power source based on the current SOH of the power source and SOHs of other utilized power sources. As an example, a power source with a reduced SOH may be loaded less than and/or less frequently than a power source having a higher SOH. As another example, a power source with a reduced SOH may be charged more often than a power source with a higher SOH. As another example, the BMM 140 may, when the current SOH is less than the first predetermined SOH, indicate that the power source has predetermined amount of life left and perform a countermeasure, such as request and/or schedule maintenance to service the power source. The BMM 140 may determine if SOH is below a second predetermined SOH indicating that the power source is at its EOL. If yes, the BMM 140 may isolate and prevent usage of the power source and/or generate a signal indicating that the power source should be replaced. The method may end at 1724.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium.

The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A state of health (SOH) based control system comprising:
a memory configured to store an algorithm including instructions for determining a SOH of a power source; and
a control module configured to receive a voltage signal indicating a voltage of the power source and execute the instructions including
determining a state of charge (SOC) of the power source,
generating a differential signal based on a change in the voltage and a change in the state of charge,
determining an inflection point and an end of charge point of the differential signal,
determining the SOH of the power source based on the inflection point and the end of charge point, and
performing at least one of a control operation or a countermeasure based on the SOH.

2. The SOH based control system of claim 1, wherein the control module is configured to differentiate voltage versus charge of the power source to provide the differential signal.

3. The SOH based control system of claim 1, wherein the inflection point is at least one of a last inflection point in a charge cycle of the power source or a first inflection point in a discharge cycle of the power source.

4. The SOH based control system of claim 1, wherein the end of charge point refers to a SOC between a SOC of the inflection point and a full or near full SOC of the power source.

5. The SOH based control system of claim 1, wherein the end of charge point refers to a full or near full SOC of the power source.

6. The SOH based control system of claim 1, wherein the control module is configured to discharge the power source to a point after detection of the inflection point and then charge the power source to the end of charge point to estimate the SOH.

7. The SOH based control system of claim 1, wherein the control module is configured to charge the power source to the end of charge point and then discharge the power source past the inflection point to estimate the SOH.

8. The SOH based control system of claim 1, wherein the control module is configured to charge the power source from an intermediate SOC below a SOC of the inflection point to the end of charge point to estimate the SOH.

9. The SOH based control system of claim 1, wherein the control module is configured to determine a logarithm of the differential signal, and based on the logarithm of the differential signal, determine the inflection point and the end of charge point.

10. The SOH based control system of claim 1, wherein the control module is configured to determine the end of charge point based on the inflection point.

11. The SOH based control system of claim 1, wherein the control module is configured to filter at least one of the voltage signal and the differential signal to provide a filtered differential signal, and based on the filtered differential signal, determine the inflection point and the end of charge point.

12. The SOH based control system of claim 1, wherein the control operation includes at least one of charging or loading the power source based on the SOH of the power source.

13. The SOH based control system of claim 1, further comprises a plurality of sensors configured to generate the voltage signal and a charge signal, the charge signal indicating the SOC of the power source,
wherein the control module is configured to determine the SOC based on the charge signal.

14. A vehicle system comprising:
the SOH based control system of claim 1; and
a plurality of loads of a vehicle,
wherein the control module is configured, based on the SOH, to control loading of the power source including selective connection of the power source to one or more of the plurality of loads.

15. A state of health (SOH) based method comprising:
receiving a voltage signal at a control module indicating a voltage of a power source;
determining a state of charge (SOC) of the power source;
generating a differential signal based on a change in the voltage and a change in the state of charge;
determining an inflection point and an end of charge point of differential signal;
determining the SOH of the power source based on the inflection point and the end of charge point; and
performing at least one of a control operation or a countermeasure based on the SOH.

15. The SOH based method of claim 14, further comprising differentiating voltage versus charge of the power source to provide the differential signal.

16. The SOH based method of claim 14, wherein the inflection point is at least one of a last inflection point in a charge cycle of the power source or a first inflection point in a discharge cycle of the power source.

17. The SOH based method of claim 14, wherein the end of charge point refers to a SOC between a SOC of the inflection point and a full or near full SOC of the power source.

18. The SOH based method of claim 14, wherein the end of charge point refers to a full or near full SOC of the power source.

19. The SOH based method of claim 14, further comprising at least one of:
discharging the power source to a point after detection of the inflection point and then charging the power source to the end of charge point to estimate the SOH;
charging the power source to the end of charge point and then discharging the power source past the inflection point to estimate the SOH; or charging the power source from an intermediate SOC below a SOC of the inflection point to the end of charge point to estimate the SOH.

20. The SOH based method of claim 14, further comprising determining a logarithm of the differential signal, and based on the logarithm of the differential signal, determining the inflection point and the end of charge point.
